(19) United States
(12) Patent Application Publication
(10) Pub. No.: US 2024/0142522 A1
(43) Pub. Date: May 2, 2024

(54) ELECTRONIC DEVICE

(71) Applicant: Innolux Corporation, Miaoli County (TW)

(72) Inventors: Chih-Yung Hsieh, Miaoli County (TW); Chen-Lin Yeh, Miaoli County (TW); Jen-Hai Chi, Miaoli County (TW)

(73) Assignee: Innolux Corporation, Miaoli County (TW)

(21) Appl. No.: 18/480,519

(22) Filed: Oct. 4, 2023

Related U.S. Application Data
(60) Provisional application No. 63/421,582, filed on Nov. 2, 2022.

(30) Foreign Application Priority Data
Jun. 14, 2023 (CN) 202310704377.4

(51) Int. Cl. G01R 31/319; G01R 1/067; G01R 1/20

(52) U.S. Cl. CPC G01R 31/31926; G01R 1/06766; G01R 1/06794; G01R 1/20

(57) ABSTRACT

An electronic device is provided. The electronic device includes a plurality of units. The plurality of units includes a first unit. The first unit includes a first electronic component and a test circuit. The test circuit is electrically connected to the first electronic component. The test circuit includes a coil circuit.

### CROSS-REFERENCE TO RELATED APPLICATION

This application claims the priority benefit of U.S. provisional application Ser. No. 63/421,582, filed on Nov. 2, 2022 and China application serial no. 202310704377.4, filed on Jun. 14, 2023. The entirety of each of the above-mentioned patent applications are hereby incorporated by reference herein and made a part of this specification.

### BACKGROUND

### Technical Field

The disclosure relates to an electronic device for detecting electronic components.

### Description of Related Art

Electronic devices may utilize parameters of electronic components to provide different functions. For example, a parameter may be a resistance value, a capacitance value, an inductance value, or an output light. However, when the connection of the electronic component is abnormal (e.g., abnormal disconnection, abnormal short circuit, or connection error), the electronic device cannot provide expected functions by utilizing the parameters of the electronic component. Therefore, how to inspect the connection of the electronic components in the electronic device is one of the research focuses of those skilled in the art.

### SUMMARY

An electronic device having electronic components is provided in this disclosure. The electronic device provides a mechanism for inspecting the connection of electronic components.

According to an embodiment of the disclosure, an electronic device includes multiple units. The units include a first unit. The first unit includes a first electronic component and a test circuit. The test circuit is electrically connected to the first electronic component. The test circuit includes a coil circuit.

According to an embodiment of the disclosure, an electronic device includes multiple units. The units include a first unit. The first unit includes a first electronic component and a test circuit. The test circuit includes a photoelectrical component. A first end of the photoelectric component is electrically connected to a first end of the first electronic component, and a second end of the photoelectric component is electrically connected to a second end of the first electronic component.

According to an embodiment of the disclosure, an electronic device includes multiple units and a coil circuit. The units include a first unit and a second unit. The first unit includes a first electronic component. The second unit is adjacent to the first unit. The second unit includes a second electronic component. The coil circuit receives a trigger signal through wireless transmission, and provides a test signal to the first electronic component and the second electronic component.

### BRIEF DESCRIPTION OF THE DRAWINGS

FIG. 1 is a schematic diagram of an electronic device according to a first embodiment of the disclosure.

FIG. 2 is a schematic diagram of a unit according to an embodiment of the disclosure.

FIG. 3 is a waveform diagram of a trigger signal and a test signal according to an embodiment of the disclosure.

FIG. 4 is a schematic diagram of a unit according to an embodiment of the disclosure.

FIG. 5A to FIG. 5C respectively are schematic diagrams of the test circuit according to an embodiment of the disclosure.

FIG. 6A to FIG. 6C respectively are schematic diagrams of a trigger signal sending circuit according to an embodiment of the disclosure.

FIG. 7 is a schematic diagram of a unit according to an embodiment of the disclosure.

FIG. 8 is a schematic diagram of a unit according to an embodiment of the disclosure.

FIG. 9 is a schematic diagram of an electronic device according to a second embodiment of the disclosure.

FIG. 10 is a schematic diagram of an electronic device according to a third embodiment of the disclosure.

FIG. 11 is a schematic diagram of an electronic device according to a fourth embodiment of the disclosure.

### DETAILED DESCRIPTION OF DISCLOSED EMBODIMENTS

The disclosure may be understood by referring to the following detailed description in conjunction with the accompanying drawings as described below. It should be noted that, for purposes of clarity and easy understanding by readers, each drawing of the disclosure depicts a part of an electronic device, and some components in each drawing may not be drawn to scale. In addition, the number and size of each device depicted in the drawings are illustrative only and not intended to limit the scope of the disclosure.

Certain terms are used throughout the description and claims below to refer to specific components. It should be understood by those skilled in the art, manufacturers of electronic equipment may refer to components by different names. The disclosure does not intend to distinguish between components that differ in name but not function. In the following description and in the claims, the terms “comprising”, “including”, and “having” are used in an open-ended manner, and should therefore be construed to mean “including but not limited to . . . ”, therefore, when the terms “comprising”, “including”, and/or “having” are used in the description, it indicates the existence of corresponding features, regions, steps, operations, and/or components, but are not limited to the existence of one or more corresponding features, regions, steps, operation, and/or components.

It should be understood that when a component is referred to as being “coupled to”, “connected to”, or “conducted to” another component, the component may be directly connected to another component and an electrical connection may be established directly, or there may be an intermediate component between these components for a relay electrical connection (indirect electrical connection). In contrast, when a component is referred to as being “directly coupled to,” “directly connected to”, or “directly connected to” another component, there are no intermediate components present.

Although terms such as first, second, third, etc. may be used to describe various constituent components, such constituent components are not limited by these terms. The terms are only used to distinguish a constituent component from other constituent components in the specification. Claims may not use the same terms, but may use the terms first, second, third, etc. with respect to the required order of the components. Therefore, in the following description, the first constituent component may be the second constituent component in the claims.

The electronic device of the disclosure may include a display device, an antenna device, a sensing device, a light-emitting device, a touch display device, a curved display device, or a free shape display, but not limited thereto. The electronic device may include a bendable or flexible electronic device. The electronic device may, for example, comprise liquid crystal, diode, quantum dot (QD), fluorescence, phosphor, other suitable display materials, or a combination of the materials thereof, but not limited thereto. Diodes include light-emitting diodes, photodiodes, or varactors. The light-emitting diode may include, for example, an organic light-emitting diode (OLED), a mini light-emitting diode (mini LED), a micro light-emitting diode (micro LED), or a quantum dot light-emitting diode (quantum dot LED, which may include QLED, QDLED), or other suitable materials, or a combination thereof, but not limited thereto. The display device may include, for example, but not limited to, a spliced display device. The antenna device may be, for example, a liquid crystal antenna, but not limited thereto. The antenna device may, for example, include an antenna splicing device, but not limited thereto. It should be noted that, the electronic device may be any arrangement and combination of the foregoing, but not limited thereto. In addition, the shape of the electronic device may be rectangular, circular, polygonal, a shape with curved edges, or other suitable shapes. The electronic device may have peripheral systems such as a driving system, a control system, a light source system, etc. to support a display device, an antenna device, or a spliced device, but the disclosure is not limited thereto. The sensing device may include a camera, an infrared sensor, or a fingerprint sensor, etc., and the disclosure is not limited thereto. In some embodiments, the sensing device may further include a flash, an infrared (IR) light source, other sensors, electronic components, or a combination thereof, but not limited thereto.

In the disclosure, the embodiments use “unit” as a unit for describing a specific region including at least one functional circuit for at least one specific function. The region of a “unit” depends on the unit used to provide a specific function. For example, when the electronic device is a display device, the units are respectively pixel units, and the region of the pixel unit may have the function of displaying and/or emitting light; when the electronic device is an antenna device, the units are respectively modulation units, and the region of the modulation unit may have the function of modulating electromagnetic waves. Adjacent units may share the same parts or wires, but may also contain specific parts within themselves. For example, adjacent units may share the same scan line or the same data line, but a unit may also have its own electronic components. Electronic components may include passive and active components, such as capacitors, resistors, inductors, transistors, and the like. In some embodiments, multiple interleaved signal lines may define a region of multiple units. For example, two adjacent data lines and two adjacent scan lines may be used to interleave to define a unit region, but the disclosure is not limited thereto.

It should be noted that technical features in different embodiments described below may be replaced, reorganized or mixed with each other to form another embodiment without departing from the spirit of the disclosure.

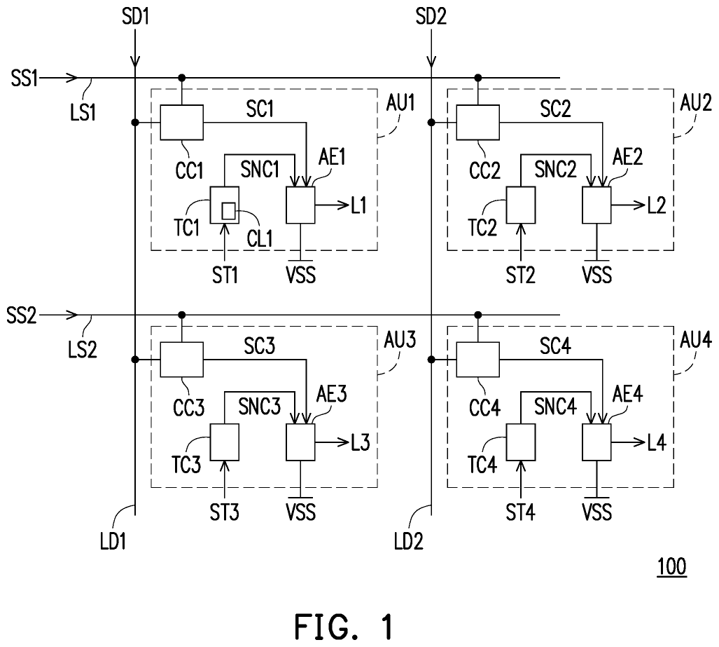

Referring to FIG. 1, which is a schematic diagram of an electronic device according to a first embodiment of the disclosure. In this embodiment, the electronic device 100 is, for example, a display device, an antenna device, or a sensing device. The electronic device 100 includes units AU1 to AU4. The units AU1 to AU4 can, for example, form a unit array, but the disclosure is not limited thereto.

In this embodiment, each of the units AU1 to AU4 includes an electronic component and a test circuit. Taking this embodiment as an example, the unit AU1 (first unit) includes an electronic component AE1 (first electronic component) and a test circuit TC1. The unit AU2 includes an electronic component AE2 and a test circuit TC2. The unit AU3 includes an electronic component AE3 and a test circuit TC3. The unit AU4 includes an electronic component AE4 and a test circuit TC4.

The test circuit TC1 receives the trigger signal ST1 through wireless transmission in the test mode, and tests the connection of the electronic component AE1 according to the trigger signal ST1. Furthermore, the test circuit TC1 includes a coil circuit CL1. In the test mode, the coil circuit CL1 receives an external trigger signal ST1 through wireless transmission, and provides a test signal SNC1 to the electronic component AE1. Similarly, the test circuits TC2, TC3, and TC4 may respectively receive the trigger signals ST2, ST3, and ST4 through wireless transmission in the test mode, and test the connection of the electronic components AE2, AE3, and AE4 according to the trigger signals ST2, ST3, and ST4. Taking the unit AU1 as an example, the coil circuit CL1 in the test circuit TC1 receives the trigger signal ST1 and further provides a test signal SNC1 to the electronic component AE1 to test whether the connection of the electronic component AE1 is abnormal.

Similarly, the coil circuit in the test circuit TC2 receives the trigger signal ST2, converts the trigger signal ST2 into a test signal SNC2, and further provides the test signal SNC2 to the electronic component AE2 to test whether the connection of the electronic component AE2 is abnormal. The coil circuit in the test circuit TC3 receives the trigger signal ST3, converts the trigger signal ST3 into a test signal SNC3, and further provides the test signal SNC3 to the electronic component AE3 to test whether the connection of the electronic component AE3 is abnormal. The coil circuit in the test circuit TC4 receives the trigger signal ST4, converts the trigger signal ST4 into a test signal SNC4, and further provides the test signal SNC4 to the electronic component AE4 to test whether the connection of the electronic component AE4 is abnormal.

It is worth mentioning here that in the test mode, the test circuits TC1 to TC4 respectively provide corresponding test signals according to the received trigger signals. The electronic components AE1 to AE4 respectively operate in response to corresponding test signals in the test mode. In this way, in the test mode, the connection status of the electronic components AE1 to AE4 may be acquired. In addition, the test circuits TC1 to TC4 receive one of the trigger signals ST1 to ST4 through wireless transmission. In this way, in the test mode, the situation of using other external electronic devices to inspect the connection of electronic components may be avoided or reduced, and the convenience of the connection inspection of the electronic components in the electronic device 100 may be improved.

In this embodiment, the trigger signals ST1 to ST4 may have the same waveform. The trigger signals ST1 to ST4 may be the same trigger signal. Therefore, the test signals SNC1 to SNC4 may be the same signal. In some embodiments, the waveforms of the trigger signals ST1 to ST4 are not completely the same. Therefore, the waveforms of the test signals SNC1 to SNC4 may not be completely the same.

In this embodiment, the electronic device 100 including four units AU1 to AU4 is taken as an example. However, the disclosure is not limited to the number or arrangement of units. The number of units in the disclosure may be one or more.

In this embodiment, the unit AU1 further includes a control circuit CC1. The control circuit CC1 is electrically connected to the first end of the electronic component AEL In the operation mode, the control circuit CC1 provides an operation signal SC1 to the electronic component AE1. The unit AU2 further includes a control circuit CC2. The control circuit CC2 is coupled to the electronic component AE2. The control circuit CC2 provides an operation signal SC2 to the electronic component AE2 in the operation mode. The unit AU3 further includes a control circuit CC3. The control circuit CC3 is coupled to the electronic component AE3. The control circuit CC3 provides an operation signal SC3 to the electronic component AE3 in the operation mode. Furthermore, the unit AU4 further includes a control circuit CC4. The control circuit CC4 is coupled to the electronic component AE4. The control circuit CC4 provides an operation signal SC4 to the electronic component AE4 in the operation mode.

In this embodiment, the electronic device 100 further includes the scan lines LS1 and LS2 and the data lines LD1 and LD2, but the disclosure is not limited thereto. The scan line LS1 is coupled to the control circuits CC1 and CC2. The scan line LS2 is coupled to the control circuits CC3 and CC4. The data line LD1 is coupled to the control circuits CC1 and CC3. The data line LD2 is coupled to the control circuits CC2 and CC4. The electronic device 100 may provide the scan signal SS1 to the control circuits CC1 and CC2 through the scan line LS1 during the first period of the operation mode, and provide the scan signal SS2 to the control circuit CC3 and CC4 through the scan line LS2 during the second period of the operation mode. Therefore, the control circuit CC1 provides the operation signal SC1 according to the data signal SD1 on the data line LD1 in the first period. The control circuit CC2 provides the operation signal SC2 according to the data signal SD2 on the data line LD2 in the first period. The control circuit CC3 provides the operation signal SC3 according to the data signal SD1 on the data line LD1 in the second period. The control circuit CC4 provides the operation signal SC4 according to the data signal SD2 on the data line LD2 in the first period.

In this embodiment, the first end of the electronic component AE1 is electrically connected to the control circuit CC1. The second end of the electronic component AE1 is electrically connected to the reference low voltage VSS (e.g., ground, the disclosure is not limited thereto).

Taking the unit AU1 as an example, the electronic component AE1 is, for example, a light-emitting component. The light-emitting component may be a light-emitting diode of any form. The first end of the electronic component AE1 is electrically connected to the test circuit TC1, and the second end of the electronic component AE1 is electrically connected to the reference low voltage VSS. The first end of the electronic component AE1 may be an anode. The second end of the electronic component AE1 may be a cathode. In this example, when the connection of the electronic component AE1 in the unit AU1 is correct, the electronic component AE1 is in a forward bias state in response to the test signal SNC1 in the test mode (i.e., the voltage of the first end of the electronic component AE1 is greater than the voltage of the second end of the electronic component AE1). Thus, the electronic component AE1 provides a light signal L1. In other words, when the electronic component AE1 provides the light signal L1 in the test mode, the connection of the electronic component AE1 in the unit AU1 is determined to be correct. On the other hand, if the connection of the electronic component AE1 in the unit AU1 is abnormal (e.g., the electronic component AE1 is disconnected, short-circuited, or the cathode and anode connections are wrong). Then the electronic component AE1 does not provide the light signal L1 in the test mode. In other words, when the electronic component AE1 does not provide the light signal L1 in the test mode, the connection of the electronic component AE1 in the unit AU1 is determined to be abnormal. In this example, the light signal L1 is a light signal of red light, blue light, green light, or other colors. In the operation mode, when the connection of the electronic component AE1 in the unit AU1 is correct, the electronic component AE1 is in a forward bias state in response to the operation signal SC1 (i.e., the voltage of the first end of the electronic component AE1 is greater than the voltage of the second end of the electronic component AE1).

Taking the unit AU1 again as an example, the electronic component AE1 is, for example, a modulation component. The modulation component may be a varactor. The first end of the electronic component AE1 is electrically connected to the test circuit TC1, and the second end of the electronic component AE1 is electrically connected to the reference low voltage VSS (e.g., ground, the disclosure is not limited thereto). The first end of the electronic component AE1 may be a cathode. The second end of the electronic component AE1 may be an anode. In this example, when the connection of the electronic component AE1 in the unit AU1 is correct, the electronic component AE1 is in a forward bias state in response to the test signal SNC1 in the test mode (i.e., the voltage of the first end of the electronic component AE1 is greater than the voltage of the second end of the electronic component AE1). Thus, the electronic component AE1 provides a light signal L1. In other words, when the electronic component AE1 provides the light signal L1 in the test mode, the connection of the electronic component AE1 in the unit AU1 is determined to be correct. On the other hand, if the connection of the electronic component AE1 in the unit AU1 is abnormal (e.g., the electronic component AE1 is disconnected, short-circuited, or the cathode and anode connections are wrong). Then the electronic component AE1 does not provide the light signal L1 in the test mode. In other words, when the electronic component AE1 does not provide the light signal L1 in the test mode, the connection of the electronic component AE1 in the unit AU1 is determined to be abnormal. In this example, the light signal L1 is an infrared signal. The light signal L1 is a light signal generated by the recombination of electrons and electron holes located near the PN junction in the electronic component AE1 based on the forward bias state. In the operation mode, when the connection of the electronic component AE1 in the unit AU1 is correct, the electronic component AE1 is in a reverse bias state in response to the operation signal SC1 (i.e., the voltage of the first end of the electronic component AE1 is less than the voltage of the second end of the electronic component AE1) for modulating at least one of the frequency, phase, and amplitude of the electromagnetic waves output and input from the electronic device 100.

Similar to the aforementioned operation of the unit AU1, the disclosure may determine whether the connection of the electronic components AE2 to AE4 is correct based on the light signals L2 to L4 provided by the units AU2 to AU4 in the test mode.

In this embodiment, in the test mode, the light signals provided by the electronic components AE1 to AE4 may be captured by an image capture device. For example, if the image capture device does not capture the light signal L1 from the electronic component AE1 in the test mode, it means that the connection of the electronic component AE1 is abnormal.

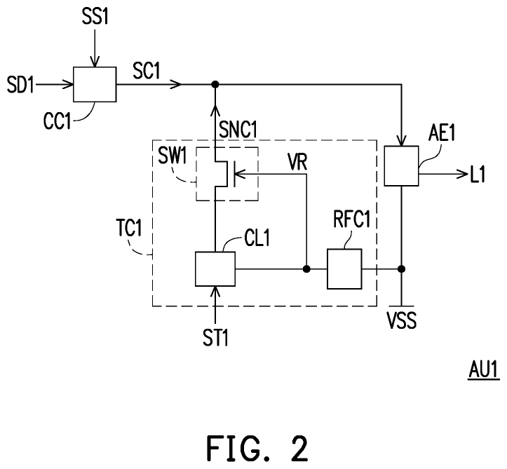

Referring to FIG. 2, FIG. 2 is a schematic diagram of a unit according to an embodiment of the disclosure. In this embodiment, the unit AU1 is suitable for the electronic device 100 shown in FIG. 1. The test circuit TC1 of the unit AU1 further includes a switch circuit SW1. The first end of the electronic component AE1 is electrically connected to the control circuit CC1. The second end of the electronic component AE1 is electrically connected to the reference low voltage VSS. In addition, the first end of the test circuit TC1 is electrically connected to the first end of the electronic component AE1. The second end of the test circuit TC1 is electrically connected to the second end of the electronic component AE1. Specifically, the coil circuit CL1 is electrically connected to the first end of the electronic component AE1 through the switch circuit SW1. A first end of the switch circuit SW1 is coupled to the coil circuit CL1. The second end of the switch circuit SW1 is coupled to the first end of the electronic component AE1. The control end of the switch circuit SW1 receives the reference voltage VR. The switch circuit SW1 is turned on or off according to the reference voltage VR1.

When the electronic device is an antenna device, the test circuit TC1 may further include a radio frequency isolation circuit RFC1. The radio frequency isolation circuit RFC1 is electrically connected to the coil circuit CL1 and the electronic component AE1. The radio frequency isolation circuit RFC1 prevents the intensity of the radio frequency in the electronic component AE1 from being reduced. In some embodiments, the radio frequency isolation circuit RFC1 may be omitted based on actual usage requirements.

In this embodiment, the reference voltage VR is provided by, for example, the radio frequency isolation circuit RFC1 or an external voltage circuit (not shown), and the disclosure is not limited to the method of providing the reference voltage VR. In this embodiment, the coil circuit CL1 may be implemented by an induction coil or an inductor. The coil circuit CL1 receives the trigger signal ST1 through magnetic field coupling.

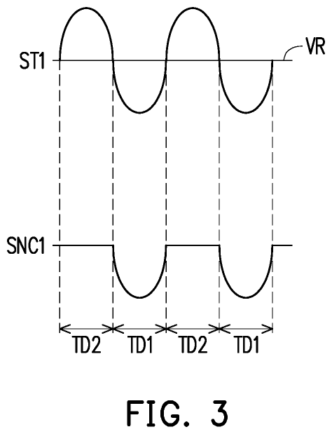

Referring to FIG. 2 and FIG. 3 at the same time, FIG. 3 is a waveform diagram of a trigger signal and a test signal according to an embodiment of the disclosure. In this embodiment, the electronic component AE1 is, for example, a modulation component. The voltage value of the test signal SNC1 is less than the voltage value of the reference voltage VR. When the voltage value of the trigger signal ST1 is less than the voltage value of the reference voltage VR, the switch circuit SW1 is turned on to transmit the test signal SNC1. In this embodiment, the trigger signal ST1 is an AC signal. The voltage value of the reference voltage VR is substantially equal to the voltage value of the reference low voltage VSS. The switch circuit SW1 is realized by, for example, an N-type transistor (but the disclosure is not limited thereto). Therefore, in the time period TD1 when the voltage difference between the voltage value of the reference voltage VR minus the voltage value of the trigger signal ST1 is greater than the threshold voltage value of the switch circuit, the switch circuit SW1 is turned on for the time period TD1 to transmit the test signal SNC1 in the trigger signal ST1.

On the other hand, in the time period TD2 when the voltage difference between the voltage value of the reference voltage VR minus the voltage value of the trigger signal ST1 is less than or equal to the threshold voltage value of the switch circuit, the switch circuit SW1 is turned off for the time period TD2.

Based on the above, the test signal SNC1 is at least part of the negative half cycle signal of the trigger signal ST1. The switch circuit SW1 transmits the test signal SNC1 to the first end of the electronic component AE1. It should be noted that since the voltage value of the reference voltage VR is substantially equal to the voltage value of the reference low voltage VSS, thus the voltage value of the test signal SNC1 is less than the voltage value of the reference low voltage VSS. If the connection of the electronic component AE1 is correct, the electronic component AE1 enters the forward voltage state during the time period TD1 based on the voltage value of the test signal SNC1 and the reference low voltage VSS. During the time period TD1, the electronic component AE1 provides the light signal L1.

In some embodiments, the switch circuit SW1 may be implemented by other suitable types of transistor switches.

In some embodiments, the switch circuit SW1 may include a determination circuit and a switch (not shown). The determination circuit determines the voltage value of the trigger signal ST1 and the voltage value of the reference voltage VR. When the voltage value of the trigger signal ST1 is less than the voltage value of the reference voltage VR, the switch circuit SW1 is turned on. Therefore, the test signal SNC1 in the trigger signal ST1 is transmitted. On the other hand, when the voltage value of the trigger signal ST1 is greater than or equal to the voltage value of the reference voltage VR, the switch circuit SW1 is turned off.

In some embodiments, the switch circuit SW1 may be omitted. Therefore, in the test mode, the electronic component AE1 enters the forward voltage state and the reverse voltage state, and provides the light signal L1 in the forward voltage state.

In some embodiments, the electronic component AE1 is, for example, a light-emitting component. The voltage value of the test signal SNC1 is greater than the voltage value of the reference voltage VR. When the voltage value of the trigger signal ST1 is greater than the voltage value of the reference voltage VR, the switch circuit SW1 is turned on to transmit the test signal SNC1. In this embodiment, the trigger signal ST1 is an AC signal. The voltage value of the reference voltage VR is substantially equal to the voltage value of the reference low voltage VSS. Thus, the test signal SNC1 is at least part of the positive half cycle of the trigger signal ST1. The switch circuit SW1 transmits the test signal SNC1 to the first end of the electronic component AE1. The switch circuit SW1 is realized by, for example, a P-type transistor (but the disclosure is not limited thereto).

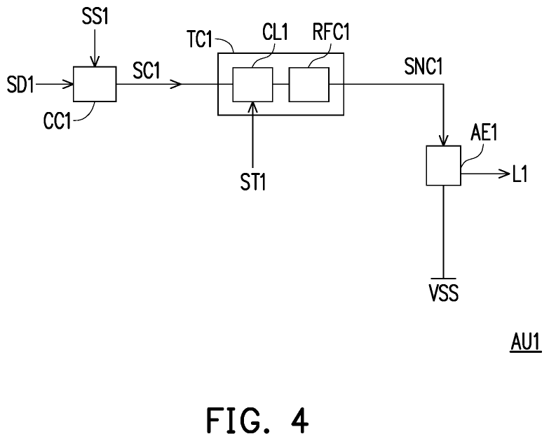

Referring to FIG. 4, FIG. 4 is a schematic diagram of a unit according to an embodiment of the disclosure. In this embodiment, the unit AU1 is suitable for the electronic device 100 shown in FIG. 1. The unit AU1 includes an electronic component AE1, a test circuit TC1, and a control circuit CC1. The first end of the test circuit TC1 is electrically connected to the control circuit CC1. The second end of the test circuit TC1 is electrically connected to the electronic component AE1. The first end of the electronic component AE1 is electrically connected to the second end of the test circuit TC1. The second end of the electronic component AE1 is electrically connected to the reference low voltage VSS. The test circuit TC1 includes a coil circuit CL1. In the test mode, the coil circuit CL1 receives the trigger signal ST1 through wireless transmission, and provides the test signal SNC1 to the first end of the electronic component AE1. In the operation mode, the test circuit TC1 provides the operation signal SC1 provided by the control circuit CC1 to the first end of the electronic component AE1. When the electronic component is a light-emitting component, the control circuit CC1 provides a forward bias voltage to the electronic component AE1, so that the electronic component AE1 provides display and/or light-emitting functions. When the electronic component is a modulation component, the control circuit CC1 provides a reverse bias voltage to the electronic component AE1, so that the electronic component AE1 provides the function of modulating electromagnetic waves. In some embodiments, the test circuit TC1 may further include a radio frequency isolation circuit RFC1. The radio frequency isolation circuit RFC1 is electrically connected to the coil circuit CL1 and the electronic component AE1.

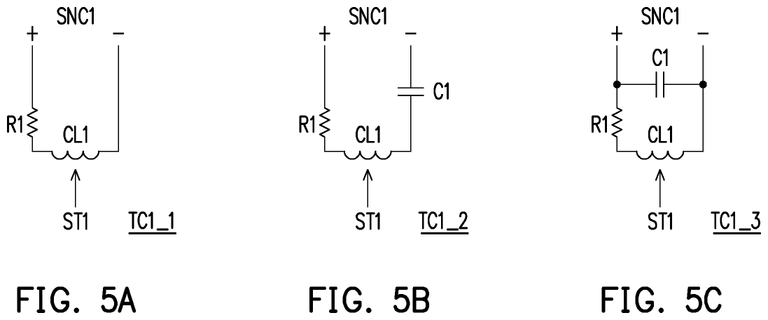

FIG. 5A to FIG. 5C respectively are schematic diagrams of the test circuit according to an embodiment of the disclosure. FIG. 5A to FIG. 5C respectively illustrate different implementation aspects of the test circuit. In FIG. 5A, the test circuit TC1_1 includes a coil circuit CL1 and a resistor R1. The first end of the coil circuit CL1 is coupled to the first output end of the test circuit TC1_1. The resistor R1 is coupled between the second output end of the test circuit TC1_1 and the second end of the coil circuit CL1. The coil circuit CL1 may be implemented by an inductor. The coil circuit CL1 receives the trigger signal ST1 through magnetic field coupling.

In FIG. 5B, the test circuit TC1_2 includes a capacitor C1, a coil circuit CL1, and a resistor R1. The first end of the capacitor C1 is coupled to the first output end of the test circuit TC1_2. The first end of the coil circuit CL1 is coupled to the second end of the capacitor C1. The resistor R1 is coupled between the second output end of the test circuit TC1_2 and the second end of the coil circuit CL1. In this embodiment, the capacitor C1, the coil circuit CL1, and the resistor R1 are coupled in series with each other. The serial coupling sequence among the capacitor C1, the coil circuit CL1, and the resistor R1 of the disclosure is not limited to this embodiment.

In FIG. 5C, the test circuit TC1_3 includes a capacitor C1, a coil circuit CL1, and a resistor R1. The capacitor C1 is coupled between the first output end of the test circuit TC1_3 and the second output end of the test circuit TC1_3. The first end of the coil circuit CL1 is coupled to the first output end of the test circuit TC1_3. The capacitor C1 is coupled between the first output end of the test circuit TC1_3 and the second output end of the test circuit TC1_3.

In this embodiment, the test circuits TC1_2 and TC1_3 respectively are resonant circuits. The test circuits TC1_2 and TC1_3 may improve the transmission efficiency of the trigger signal ST1. In this embodiment, the test circuit TC1_1 saves the setting space of the capacitor C1. Therefore, the designer may select one of the test circuits TC1_1, TC1_2, and TC1_3 based on actual usage requirements.

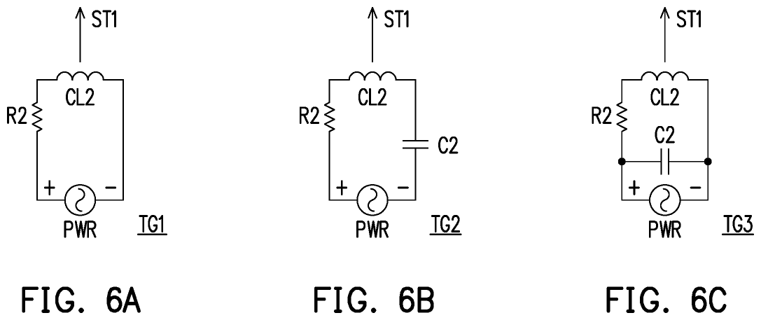

FIG. 6A to FIG. 6C respectively are schematic diagrams of a trigger signal sending circuit according to an embodiment of the disclosure. FIG. 6A to FIG. 6C respectively illustrate different implementation aspects of the trigger signal sending circuit. In FIG. 6A, the trigger signal sending circuit TG1 includes a power supply PWR, a resistor R2, and a coil circuit CL2. The first end of the resistor R2 is coupled to the first end of the power supply PWR. The coil circuit CL2 is coupled between the second end of the resistor R2 and the second end of the power supply PWR. The power supply PWR provides AC power. The coil circuit CL2 may be implemented by an inductor. The coil circuit CL2 sends the trigger signal ST1 according to the AC power.

In FIG. 6B, the trigger signal sending circuit TG2 includes a power supply PWR, a resistor R2, a coil circuit CL2, and a capacitor C2. The first end of the resistor R2 is coupled to the first end of the power supply PWR. The first end of the coil circuit CL2 is coupled to the second end of the resistor R2. The capacitor C2 is coupled between the second end of the coil circuit CL2 and the second end of the power supply PWR. In this embodiment, the power supply PWR, the resistor R2, the coil circuit CL2, and the capacitor C2 are coupled in series with each other. The serial coupling sequence among the power supply PWR, the resistor R2, the coil circuit CL2, and the capacitor C2 of the disclosure is not limited to this embodiment.

In FIG. 6C, the trigger signal sending circuit TG3 includes a power supply PWR, a resistor R2, a coil circuit CL2, and a capacitor C2. The first end of the resistor R2 is coupled to the first end of the power supply PWR. The coil circuit CL2 is coupled between the second end of the resistor R2 and the second end of the power supply PWR. The capacitor C2 is coupled between the first end of the power PWR and the second end of the power PWR.

In this embodiment, the trigger signal sending circuits TG2 and TG3 respectively are resonant circuits. The trigger signal sending circuits TG2 and TG3 may improve the transmission efficiency of the trigger signal ST1. In this embodiment, the trigger signal sending circuit TG1 saves the setting space of the capacitor C1. Therefore, the designer may select one of the trigger signal sending circuits TG1, TG2, and TG3 based on actual usage requirements.

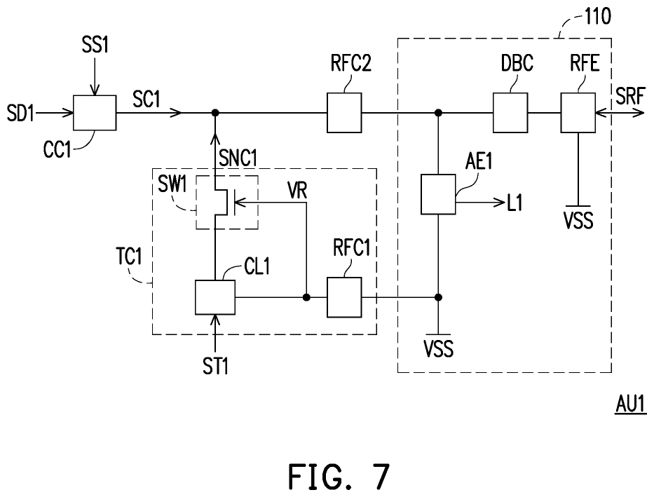

Referring to FIG. 7, FIG. 7 is a schematic diagram of a unit according to an embodiment of the disclosure. In this embodiment, the unit AU1 is, for example, a modulation unit. The unit AU1 includes a functional circuit 110, a test circuit TC1, a control circuit CC1, and a radio frequency isolation circuit RFC2. The test circuit TC1 may include a coil circuit CL1, a switch circuit SW1 and a radio frequency isolation circuit RFC1. The control circuit CC1 is electrically connected to the functional circuit 110 through the radio frequency isolation circuit RFC2. The test circuit TC1 is electrically connected to the functional circuit 110 through the radio frequency isolation circuit RFC2. The radio frequency isolation circuit RFC1 is coupled between the coil circuit CL1 and the functional circuit 110.

In this embodiment, the functional circuit 110 includes an electronic component AE1, a DC voltage isolation circuit DBC, and a radio frequency receiving component RFE. The second end of the electronic component AE1 is coupled to the reference low voltage VSS. A first end of the electronic component AE1 is coupled to the radio frequency isolation circuit RFC2, and a second end is coupled to the radio frequency isolation circuit RFC1. The radio frequency receiving component RFE is coupled to the first end of the electronic component AE1 through the DC voltage isolation circuit DBC. The radio frequency receiving component RFE is configured to receive or send a radio frequency signal SRF. The functional circuit 110 may receive, send, or process the radio frequency signal SRF based on the capacitance value provided by the electronic component AE1.

The coordinated operation of the electronic component AE1, the test circuit TC1 and the control circuit CC1 has been clearly described in the embodiments of FIG. 1 to FIG. 5C, so it is not repeated herein.

In this embodiment, the radio frequency isolation circuits RFC1 and RFC2 may prevent the intensity of the radio frequency in the electronic component AE1 from being reduced. The DC voltage isolation circuit DBC may prevent the DC voltage components of the operation signal SC1 and the test signal SNC1 at the first end of the electronic component AE1 from entering the radio frequency receiving component RFE. In this way, a short circuit may be avoided.

In some embodiments, at least one of the radio frequency isolation circuits RFC1, RFC2, and the DC voltage isolation circuit DBC may be omitted based on actual usage requirements.

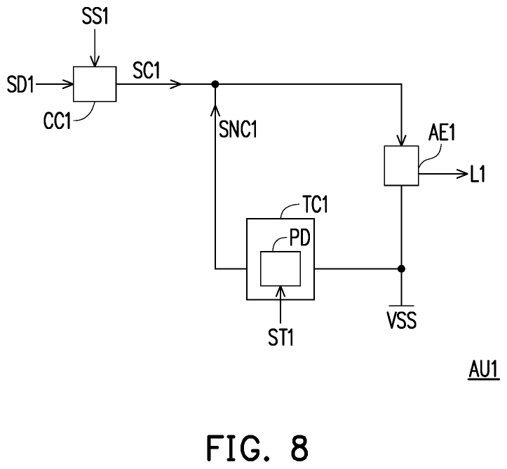

Referring to FIG. 8, FIG. 8 is a schematic diagram of a unit according to an embodiment of the disclosure. In this embodiment, the unit AU1 is suitable for the electronic device 100 shown in FIG. 1. The unit AU1 includes the electronic component AE1 and the test circuit TC1. The first end of the test circuit TC1 is electrically connected to the first end of the electronic component AE1. The second end of the test circuit TC1 is electrically connected to the second end of the electronic component AE1 and the reference low voltage VSS. The test circuit TC1 includes a photoelectric component PD. The first end of the photoelectric component PD is electrically connected to the first end of the electronic component AE1, and the second end of the photoelectric component PD is electrically connected to the second end of the electronic component AE1. The trigger signal ST1 is a light signal. The photoelectric component PD receives the trigger signal ST1 in the test mode, and generates the test signal SNC1 according to the trigger signal ST1. The photoelectric component PD may be implemented by a photodiode or other photovoltaic (PV) components.

In this embodiment, the trigger signal ST1 is, for example, an ultraviolet light signal. The light signal L1 is red light, blue light, green light, infrared light, or other signals with different wavelengths than the trigger signal ST1. Therefore, the trigger signal ST1 does not interfere with the detection of the light signal L1. The wavelength in this embodiment may be, for example, a wavelength range or a peak value of a wavelength, but not limited thereto.

In this embodiment, the unit AU1 further includes a control circuit CC1. The control circuit CC1 is electrically connected to the first end of the electronic component AE1. In some embodiments, the electronic device further includes radio frequency isolation circuits RFC1 and RFC2 (not shown). Similar to FIG. 8, the radio frequency isolation circuit RFC1 is coupled between the photoelectric component PD and the electronic component AE1, and the radio frequency isolation circuit RFC2 is coupled between the control circuit CC1 and the electronic component AE1. The implementations of the unit AU1 and the control circuit CC1 have been clearly described in the embodiments of FIG. 1 and FIG. 2, so they are not repeated herein.

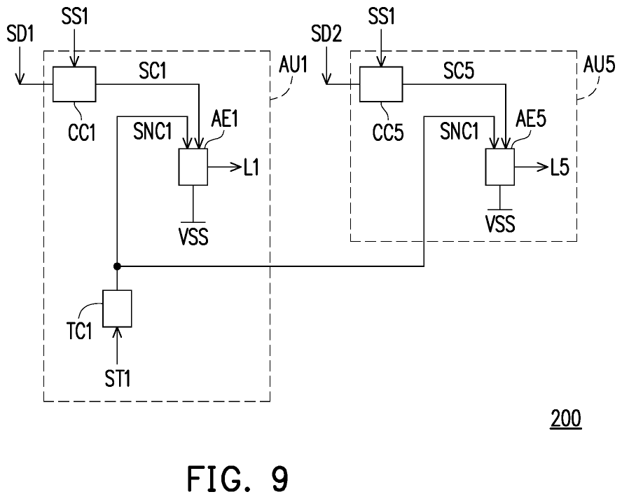

Referring to FIG. 9, FIG. 9 is a schematic diagram of an electronic device according to a second embodiment of the disclosure. In this embodiment, the electronic device 200 includes a unit AU1 (first unit) and a unit AU5 (second unit). The unit AU1 includes an electronic component AE1, a test circuit TC1, and a control circuit CC1. The unit AU1 has been clearly described in the embodiments of FIG. 1 to FIG. 5C, so it is not repeated herein.

In this embodiment, the unit AU5 includes the electronic component AE5. The electronic component AE5 is electrically connected to the test circuit TC1. In this embodiment, the first end of the electronic component AE5 is electrically connected to the test circuit TC1. The second end of the electronic component AE5 is electrically connected to the reference low voltage VSS.

The test circuit TC1 provides the test signal SNC1 to the electronic component AE1 and the electronic component AE5 in the test mode. It is thereby determined whether the connection of the electronic component AE1 in the unit AU1 and the connection of the electronic component AE5 in the unit AU5 are correct. For example, if the electronic component AE1 provides the light signal L1 in the test mode, the connection of the electronic component AE1 in the unit AU1 is correct. If the electronic component AE1 does not provide the light signal L1 in the test mode, the connection of the electronic component AE1 in the unit AU1 is abnormal. For example, if the electronic component AE5 provides the light signal L5 in the test mode, the connection of the electronic component AE5 in the unit AU5 is correct. If the electronic component AE5 does not provide the light signal L5 in the test mode, the connection of the electronic component AE5 in the unit AU5 is abnormal.

It should be noted that, in this embodiment, the unit AU1 and the unit AU5 share the test circuit TC1. In this way, the layout space of the electronic device 200 may be saved.

Furthermore, the unit AU5 further includes a control circuit CC5. The control circuit CC5 provides an operation signal SC5 to the electronic component AE5 in the operation mode.

In some embodiments, the unit AU1 and multiple units share the test circuit TC1. The disclosure is not limited by the number of units.

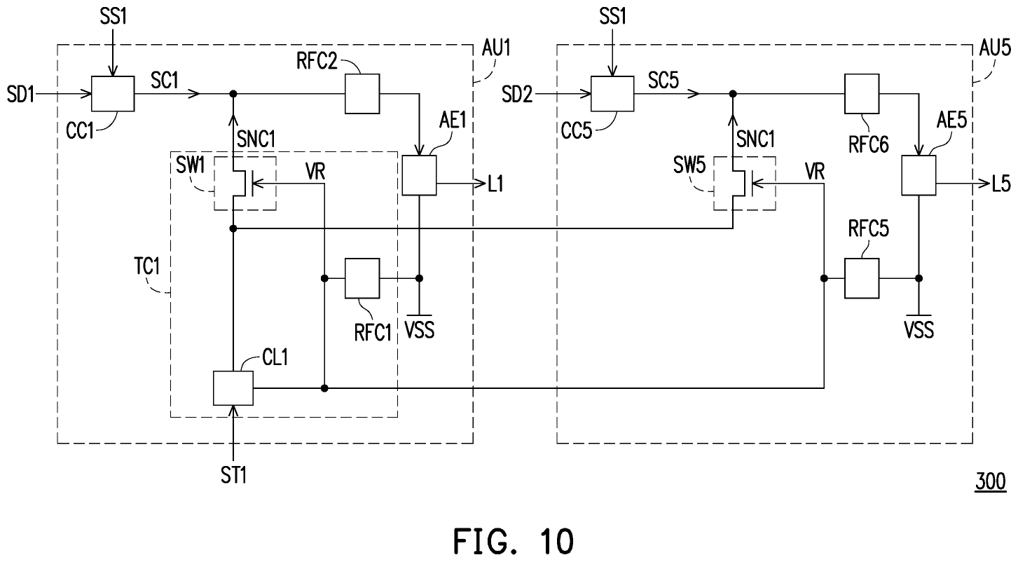

Referring to FIG. 10, FIG. 10 is a schematic diagram of an electronic device according to a third embodiment of the disclosure. In this embodiment, the electronic device 300 includes a unit AU1 (first unit) and a unit AU5 (second unit). The unit AU1 includes an electronic component AE1, a test circuit TC1, and a control circuit CC1. In some embodiments, the test circuit TC1 includes a switch circuit SW1. In some embodiments, the unit AU1 may further include radio frequency isolation circuits RFC1 and RFC2, but not limited thereto. The unit AU1 has been clearly described in the embodiments of FIG. 1 to FIG. 5C, so it is not repeated herein.

In this embodiment, the unit AU5 includes an electronic component AE5, a control circuit CC5, and a switch circuit SW5. In this embodiment, the first end of the electronic component AE5 is coupled to the test circuit TC1 and the control circuit CC5. The second end of the electronic component AE5 is coupled to the reference low voltage VSS. A first end of the switch circuit SW5 is coupled to the coil circuit CL1. The second end of the switch circuit SW5 is coupled to the first end of the electronic component AE5. The control end of the switch circuit SW5 receives the reference voltage VR.

In some embodiments, the unit AU5 may further include radio frequency isolation circuits RFC5 and RFC6. The radio frequency isolation circuit RFC5 is coupled between the coil circuit CL1 and the second end of the electronic component AE5. The radio frequency isolation circuit RFC6 is coupled to the control circuit CC5 and the first end of the electronic component AE5. The radio frequency isolation circuits RFC5 and RFC6 may prevent the intensity of the radio frequency of the electronic component AE1 from being reduced. In some embodiments, the radio frequency isolation circuits RFC5, RFC6, and the switch circuit SW5 may be omitted based on actual usage requirements.

It should be noted that, in this embodiment, the units AU1 and AU5 share the coil circuit CL1. In this way, the layout space of the electronic device 300 may be saved.

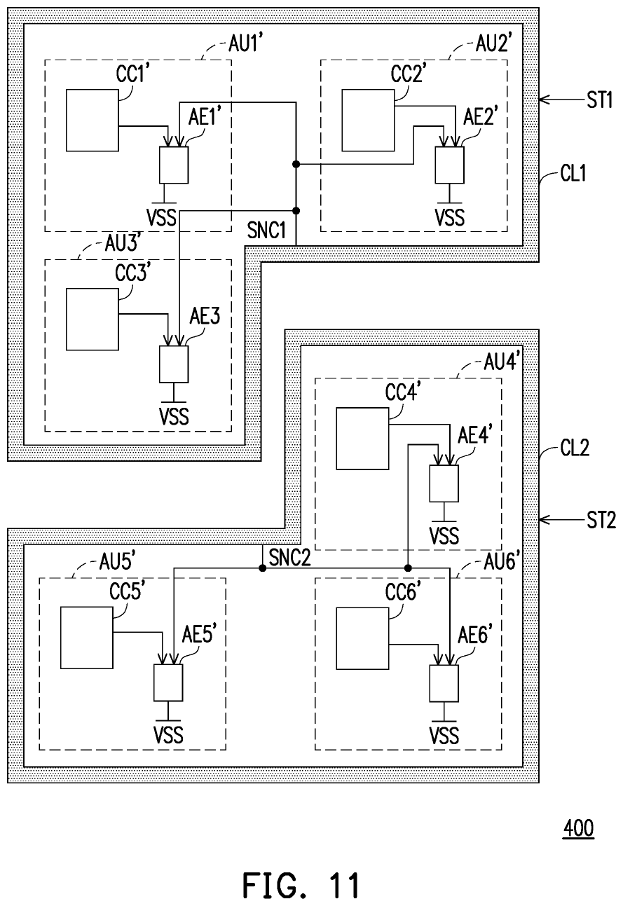

Referring to FIG. 11, FIG. 11 is a schematic diagram of an electronic device according to a fourth embodiment of the disclosure. In this embodiment, the electronic device 400 includes units AU1′ to AU6′ and coil circuits CL1 and CL2.

In this embodiment, the unit AU1′ (first unit) includes the electronic component AE1′ (first electronic component). The unit AU2′ (second unit) includes the electronic component AE2′ (second electronic component). The unit AU3′ includes the electronic component AE3′. The coil circuit CL1 is electrically connected to the electronic components AE1′ to AE3′. The coil circuit CL1 receives the trigger signal ST1 and provides a test signal SNC1 to the electronic components AE1′ to AE3′.

Furthermore, the unit AU1′ further includes a control circuit CC1′. The unit AU2′ further includes a control circuit CC2′. The unit AU3′ further includes a control circuit CC3′. In this embodiment, the operations of the control circuits CC1′ to CC3′ and the electronic components AE1′ to AE3′ are similar to the operations of the control circuit CC1 and the electronic component AE1 in FIG. 1 and FIG. 2, it is therefore not repeated herein.

In this embodiment, the coil circuit CL1 is disposed outside the units AU1′ to AU3′. The units AU1′ to AU3′ are adjacent to each other. The coil circuit CL1 surrounds the units AU1′ to AU3′.

In this embodiment, the coil circuit CL1 provides a test signal SNC1 to three electronic components (e.g., the electronic components AE1′ to AE3′). However, the disclosure is not limited thereto, the coil circuit CL1 of the disclosure provides the test signal SNC1 to one or more electronic components.

In this embodiment, the unit AU4′ includes the electronic component AE4′. The unit AU5′ includes the electronic component AE5′. The unit AU6′ includes the electronic component AE6′. The coil circuit CL2 is electrically connected to the electronic components AE4′ to AE6′. The coil circuit CL2 receives the trigger signal ST2 and provides a test signal SNC2 to the electronic components AE4′ to AE6′.

Furthermore, the unit AU4′ further includes a control circuit CC4′. The unit AU5′ further includes a control circuit CC5′. The unit AU6′ further includes a control circuit CC6′. In this embodiment, the operations of the control circuits CC4′ to CC6′ and the electronic components AE4′ to AE6′ are similar to the operations of the control circuit CC1 and the electronic component AE1 in FIG. 1 and FIG. 2, it is therefore not repeated herein.

In this embodiment, the coil circuit CL2 is disposed outside the units AU4′ to AU6′. The units AU4′ to AU6′ are adjacent to each other. The coil circuit CL1 surrounds the units AU4′ to AU6′.

In this embodiment, the coil circuit CL2 provides the test signal SNC2 to three electronic components. However, the disclosure is not limited thereto, the coil circuit CL2 of the disclosure provides the test signal SNC2 to one or more electronic components.

To sum up, in the test mode, the test circuit in the first unit provides a test signal according to the trigger signal. The first electronic component operates in response to a test signal in the test mode. In this way, in the test mode, the disclosure may acquire the connection status of the first electronic component according to the operation result of the first electronic component in response to the test signal. In addition, the test circuit receives the trigger signal through wireless transmission. In this way, in the test mode, the test circuit does not need to receive the trigger signal through an electrical connection. In this way, the inspection of the connection of the electronic components in the electronic device is more convenient.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure.

What is claimed is:

1. An electronic device, comprising:
a plurality of units, comprising a first unit, wherein the first unit comprises:
a first electronic component; and
a test circuit, electrically connected to the first electronic component and comprising a coil circuit.

2. The electronic device according to claim 1, wherein the first unit further comprises:
a control circuit, electrically connected to the first electronic component, configured to provide an operation signal to the first electronic component in an operation mode.

3. The electronic device according to claim 2, wherein
a first end of the test circuit is electrically connected to the control circuit, and
a second end of the test circuit is electrically connected to the first electronic component.

4. The electronic device according to claim 2, wherein
a first end of the test circuit is electrically connected to a first end of the first electronic component, and
a second end of the test circuit is electrically connected to a second end of the first electronic component.

5. The electronic device according to claim 4, further comprising:
a switch circuit, wherein a first end of the switch circuit is electrically connected to the coil circuit, a second end of the switch circuit is electrically connected to the first electronic component, a control end of the switch circuit receives a reference voltage,
wherein the switch circuit is turned on or off according to the reference voltage.

6. The electronic device according to claim 1, wherein in a test mode, the coil circuit receives a trigger signal through wireless transmission, and provides a test signal to the first electronic component.

7. The electronic device according to claim 6, wherein the first electronic component provides a light signal in the test mode when a connection of the first electronic component in the first unit is correct.

8. The electronic device according to claim 1, wherein the first electronic component is a light-emitting component.

9. The electronic device according to claim 8, wherein when a connection of the first electronic component in the first unit is correct, the first electronic component is in a forward bias state in a test mode and in the forward bias state in an operation mode.

10. The electronic device according to claim 1, wherein the first electronic component is a modulation component.

11. The electronic device according to claim 10, wherein when a connection of the first electronic component in the first unit is correct, the first electronic component is in a forward bias state in a test mode and in a reverse bias state in an operation mode.

12. The electronic device according to claim 10, wherein the test circuit further comprises:
a radio frequency isolation circuit, electrically connected to the coil circuit and the first electronic component.

13. The electronic device according to claim 1, wherein the units comprise a second unit, wherein the second unit comprises:
a second electronic component, electrically connected to the test circuit.

14. The electronic device according to claim 13, wherein in a test mode, the coil circuit receives a trigger signal through wireless transmission, and provides a test signal to the first electronic component and the second electronic component.

15. An electronic device, comprising:
a plurality of units comprising a first unit, wherein the first unit comprises:
a first electronic component; and
a test circuit, comprising:
a photoelectrical component, wherein a first end of the photoelectric component is electrically connected to a first end of the first electronic component, and a second end of the photoelectric component is electrically connected to a second end of the first electronic component.

16. The electronic device according to claim 15, wherein the first unit further comprises:
a control circuit, electrically connected to the first electronic component, configured to provide an operation signal to the first electronic component in an operation mode.

17. The electronic device according to claim 15, wherein in a test mode, the photoelectrical component receives a trigger signal through wireless transmission, and provides a test signal to the first electronic component.

18. The electronic device according to claim 17, wherein the first electronic component provides a light signal in the test mode when a connection of the first electronic component in the first unit is correct.

19. The electronic device according to claim 18, wherein the trigger signal is an ultraviolet light signal, wherein a wavelength of the trigger signal is different from a wavelength of the light signal.

20. An electronic device, comprising:
a plurality of units, comprising:
a first unit, comprising a first electronic component; and
a second unit, adjacent to the first unit and comprising a second electronic component; and
a coil circuit, receiving a trigger signal through wireless transmission, and providing a test signal to the first electronic component and the second electronic component.
